(19) United States
(12) Patent Application Publication
(10) Pub. No.: US 2025/0144817 A1
(43) Pub. Date: May 8, 2025

(54) CARRIER PLATFORM, DETECTION DEVICE AND BASE THEREFOR

(71) Applicants: Chengdu BOE OPtoelectronics Technology Co., Ltd., Sichuan (CN); BOE Technology Group Co., Ltd., Beijing (CN)

(72) Inventors: Xue MENG, Beijing (CN); Qiang PU, Beijing (CN); Fei ZENG, Beijing (CN); Guodong ZHOU, Beijing (CN); Xin MOU, Beijing (CN); Rongkun FAN, Beijing (CN); Jialin WANG, Beijing (CN); Haitao LIANG, Beijing (CN)

(21) Appl. No.: 18/691,068

(22) PCT Filed: Jan. 16, 2023
(86) PCT No.: PCT/CN2023/072427

§ 371 Date: Mar. 12, 2024

(51) Int. Cl. B25J 15/06

(52) U.S. Cl. CPC B25J 15/0616

(57) ABSTRACT

The present disclosure provides a carrier platform, a detection device and a base thereof. The carrier platform includes a carrier unit configured to carry a display module and a suction nozzle disposed on the carrier unit. The carrier platform further includes a negative pressure assembly, configured to provide a negative pressure to the suction nozzle to enable the suction nozzle to adsorb the display module located on the carrier unit.

### CROSS-REFERENCE

The present application is a U.S. National Stage of International Application No. PCT/CN2023/072427, filed on Jan. 16, 2023, the contents of which are incorporated herein by reference in its entirety for all purposes.

### TECHNICAL FIELD

The present disclosure relates to the field of display technologies, and in particular, to a carrier platform, a detection device and a base therefor.

### BACKGROUND

During detection of a display module, the display module may be fixed on a carrier platform. In this way, the carrier platform will carry the display module to transfer it between different detection devices, avoiding the display module being separately crimped to respective detection devices, thereby improving detection efficiency.

It should be noted that the information disclosed in the Background section above is only for enhancing the understanding of the background of the present disclosure, and thus may include information that does not constitute prior art known to those of ordinary skill in the art.

### SUMMARY

The present disclosure provides a carrier platform, a detection device and a base thereof.

According to an aspect of the present disclosure, there is provided a carrier platform. The carrier platform includes a carrier unit configured to carry a display module and a suction nozzle disposed on the carrier unit. The carrier platform further includes a negative pressure assembly, configured to provide a negative pressure to the suction nozzle to enable the suction nozzle to adsorb the display module located on the carrier unit.

According to another aspect of the present disclosure, there is provided a base for a detection device, configured to be in a detachable connection with the carrier platform; wherein the base is provided with two sets of prism components; and

when the base is connected with the carrier platform, the two sets of prism components are capable of being accommodated in the two prism avoidance cavities in a one-to-one correspondence.

According to another aspect of the present disclosure, there is provided a base for a detection device, configured to be in a detachable connection with the carrier platform, and the base is equipped with a replaceable transfer circuit; and

when the carrier platform is connected with the base, the transfer circuit is capable of being electrically connected to the crimping joint.

According to another aspect of the present disclosure, there is provided a base for a detection device, configured to be in a detachable connection with the carrier platform;

the base is provided with a plurality of sets of positioning connection components, and the carrier platform is detachably connected to the base through the positioning connection components; and

different positioning connection components are capable of being detachably connected to different carrier platforms.

According to another aspect of the present disclosure, there is provided a detection device, including the base.

It should be noted that the above general description and the following detailed description are merely exemplary and explanatory and should not be construed as limiting of the disclosure.

### BRIEF DESCRIPTION OF THE DRAWINGS

The drawings here are incorporated into the specification and constitute a part of the specification, show embodiments in consistent with the present disclosure, and are used together with the specification to explain principles of the present disclosure. Obviously, the drawings in the following description are only some embodiments of the present disclosure. For those of ordinary skill in the art, other drawings can be obtained based on these drawings without creative work.

FIG. 1 is a schematic top structural view of a carrier platform in an embodiment of the present disclosure.

FIG. 2 is a schematic three-dimensional structural diagram of a carrier platform in an embodiment of the present disclosure.

FIG. 3 is a schematic three-dimensional structural diagram of a combination of a carrier platform and a display module in an embodiment of the present disclosure.

FIG. 4 is a schematic three-dimensional structural diagram of a display module, a carrier platform and a base in an embodiment of the present disclosure.

FIGS. 5-1 to 5-3 illustrate schematic diagrams of a process of transferring a display module from a first detection device to a second detection device, where FIG. 5-1 is a schematic structural diagram of detection of a display module on a first detection device, FIG. 5-2 is a schematic structural diagram of separation of a display module and a carrier platform from a first detection device, and FIG. 5-3 is a schematic structural diagram of detection of a display module on a second detection device.

FIG. 6 is a schematic top structural view of a base in an embodiment of the present disclosure.

FIG. 7 is a schematic structural diagram of a negative pressure assembly being disposed in an accommodation cavity in an embodiment of the present disclosure, where a view direction is a first direction.

FIG. 8 is a schematic structural diagram of an elastic hollow ball being disposed in an accommodation cavity in an embodiment of the present disclosure.

FIG. 9 is a schematic structural diagram of an elastic hollow ball providing a negative pressure to a suction nozzle in an embodiment of the present disclosure.

FIG. 10 is a schematic structural diagram of cooperation between an elastic hollow ball and a negative pressure control member in an embodiment of the present disclosure.

FIG. 11 is a schematic structural diagram of a resilient box being disposed in an accommodation cavity in an embodiment of the present disclosure.

FIG. 12 is a schematic structural diagram of a resilient box providing a negative pressure to a suction nozzle in an embodiment of the present disclosure.

FIG. 13 is a schematic structural diagram of cooperation between a resilient box and a negative pressure control member in an embodiment of the present disclosure.

FIG. 14 is a schematic structural diagram of a suction nozzle being in a first state in an embodiment of the present disclosure.

FIG. 15 is a schematic structural diagram of a suction nozzle being in a second state in an embodiment of the present disclosure.

FIG. 16 is a schematic structural diagram of suction nozzles on both sides being in a second state and a suction nozzle in a middle being in a first state in an embodiment of the present disclosure.

FIG. 17 is a schematic structural diagram of suction nozzles on both sides being in a first state and a suction nozzle in a middle being in a second state in an embodiment of the present disclosure.

FIG. 18 is a schematic side structural view of a carrier platform in an embodiment of the present disclosure, where a view direction is a second direction.

FIG. 19 is a schematic diagram of distribution of suction nozzles on a carrier unit in an embodiment of the present disclosure.

FIG. 20 is a schematic diagram of distribution of suction nozzles on a carrier unit in an embodiment of the present disclosure.

FIG. 21 is a schematic diagram of distribution of suction nozzles on a carrier unit in an embodiment of the present disclosure.

FIG. 22 is a schematic diagram of distribution of suction nozzles on a carrier unit in an embodiment of the present disclosure.

FIG. 23 is a schematic diagram of distribution of suction nozzles on a carrier unit in an embodiment of the present disclosure.

FIG. 24 is a schematic diagram of the distribution of suction nozzles on a carrier unit in an embodiment of the present disclosure.

### DETAILED DESCRIPTION

Example embodiments will now be described more fully with reference to the accompanying drawings. However, the example embodiments can be implemented in a variety of forms and should not be construed as being limited to implementations set forth herein; rather, these embodiments are provided so that the present disclosure will be thorough and complete so as to convey the idea of the example embodiments to those skilled in this art. The same reference numerals in the drawings denote the same or similar structures, and the detailed description thereof will be omitted. In addition, the drawings are merely schematic representations of the present disclosure and are not necessarily drawn to scale.

Although the relative terms such as “above” and “below” are used in the specification to describe the relative relationship of one component to another component shown, these terms are only for convenience in this specification, for example, according to an example direction shown in the drawings. It will be understood that if the device shown is flipped upside down, the component described as “above” will become a component “below” another component. When a structure is “on” another structure, it may mean that a structure is integrally formed on another structure, or that a structure is “directly” disposed on another structure, or that a structure is “indirectly” disposed on another structure through other structures.

The terms “one”, “a”, “the”, “said”, and “at least one” are used to indicate that there are one or more elements/components or the like; the terms “include” and “have” are used to indicate an open meaning of including and means that there may be additional elements/components/etc. in addition to the listed elements/components/etc.; and the terms “first”, “second” and “third” etc. are used only as markers, and do not limit the number of objects.

As described above, during detection of a display module, the display module may be fixed on a carrier platform. In this way, the carrier platform will carry the display module to transfer it between different detection devices, avoiding the display module being separately crimped to respective detection devices, thereby improving detection efficiency.

The carrier platform is generally provided with a clamping mechanism to fix the carried display module. However, when the display module is a special-shaped product or a large-angle product (such as a waterfall screen with a large-angle glass cover), the clamping mechanism cannot clamp the display module.

Embodiments of the present disclosure provide a carrier platform and a detection device that cooperates with the carrier platform. Specifically, there is provided a base, on the detection device, configured to cooperate with the carrier platform.

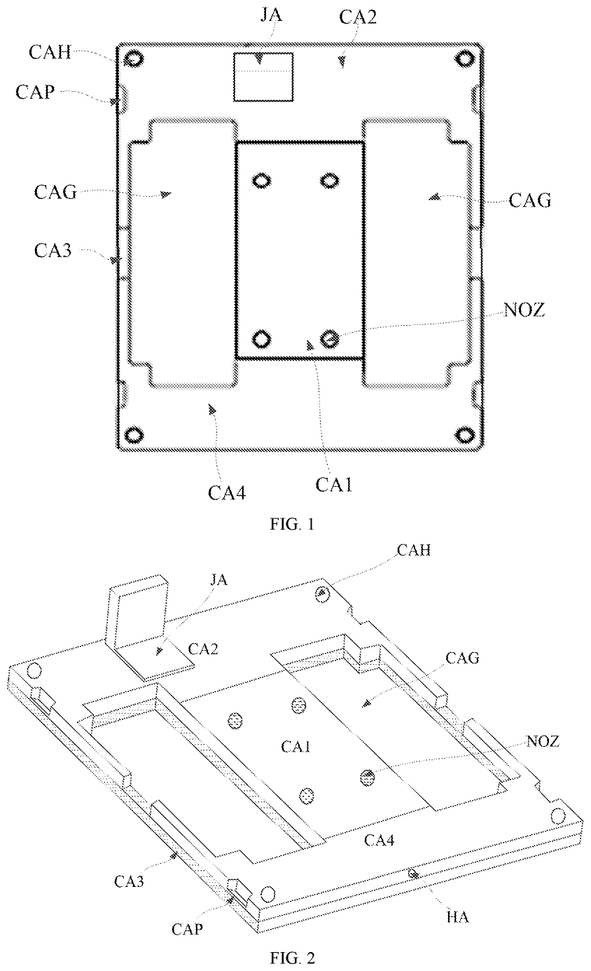

Referring to FIGS. 1 to 3, a carrier platform CA includes a carrier unit CA1 configured to carry a display module MDL and a suction nozzle NOZ disposed on the carrier unit CA1. The carrier platform CA further includes a negative pressure assembly (not shown in FIGS. 1 to 3), which is configured to provide a negative pressure for the suction nozzle NOZ to enable the suction nozzle NOZ to adsorb a display module MDL located on the carrier unit CA1.

In embodiments of the present disclosure, when the display module MDL needs to be detected, the display module MDL may be carried on the carrier unit CA1 of the carrier platform CA, and then the negative pressure is provided for the suction nozzle NOZ by the negative pressure assembly, so that the suction nozzle NOZ adsorbs the display module MDL by means of the negative pressure to achieve the fixation of the display module MDL. In the embodiments of the present disclosure, the suction nozzle NOZ is located below the display module MDL, which is not restricted by a position and form of an edge of the display module MDL, and may be applied to various forms of display modules MDL, overcoming a deficiency than a clamping mechanism fails to be suitable for the fixation of a special-shaped display module MDL and a large-angle display module MDL (such as a display module MDL of a waterfall screen). Therefore, in the embodiments of the present disclosure, the carrier platform CA has strong versatility, which can reduce detection cost of the display module MDL. In addition, in the related arts, when the display module MDL is clamped by the clamping mechanism, there is a risk of damaging the display module MDL. In the embodiments of the present disclosure, the carrier platform CA adsorbs the display module MDL through the suction nozzle NOZ, without causing the clamping damage to the display module MDL, so as to reduce the risk of damage to the display module MDL during the fixation.

Hereinafter, a structure, a principle and an effect of the carrier platform according to embodiments of the present disclosure will be further explained and described in conjunction with the accompanying drawings.

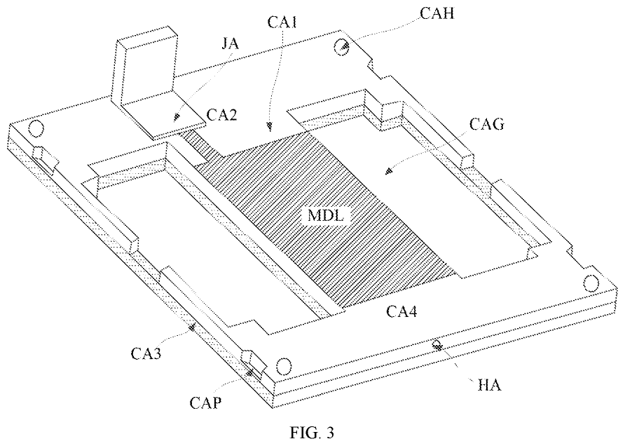

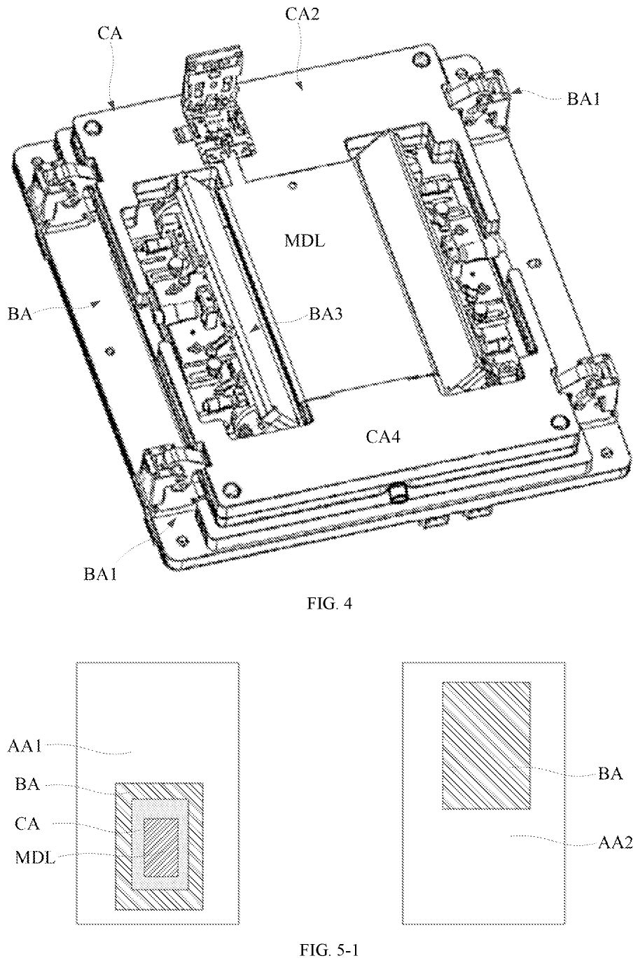

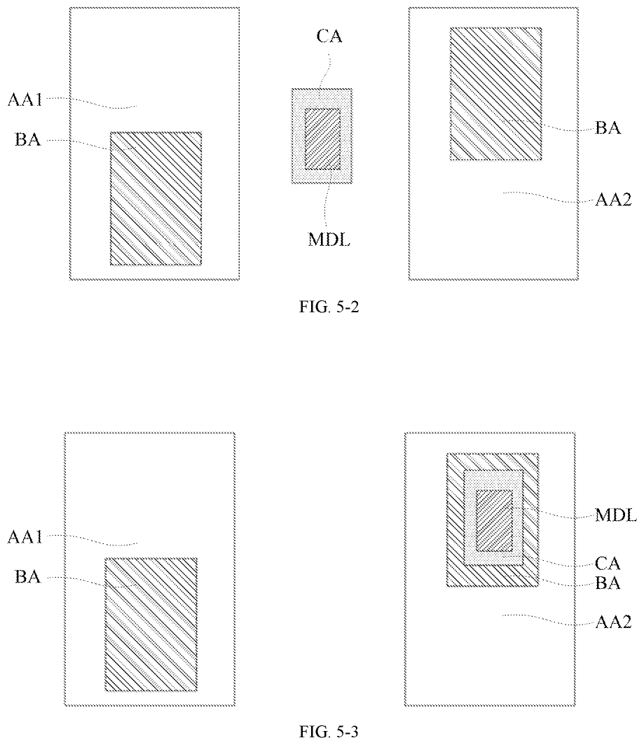

FIG. 4 shows a schematic structural diagram of cooperation between the carrier platform CA, a base BA and the display module MDL in an embodiment of the present disclosure. Referring to FIG. 4, the carrier platform CA is configured to carry the display module MDL and fix the carried display module MDL by means of adsorption. The base BA is disposed on a detection device and is configured to be in a detachable connection with the carrier platform CA, so that the carrier platform CA and the display module MDL carried by the carrier platform CA are fixed on the detection device. When the display module MDL needs to be transferred to another detection device for detection, the carrier platform CA may be separated from the base BA of the current detection device, and then the carrier platform CA may be transferred and fixed with a base BA of another detection device, realizing the transfer of the display module MDL between different detection devices. FIGS. 5-1 to 5-3 illustrate schematic diagrams of a process of transferring the display module MDL from a first detection device AA1 to a second detection device AA2 in an embodiment of the present disclosure. Referring to FIG. 5-1, the first detection device AA1 and the second detection device AA2 are each provided with the base BA, and the carrier platform CA on which the display module MDL is carried and fixed is fixedly connected to the base BA of the first detection device AA1. When the display module MDL is to be transferred, the carrier platform CA carrying the display module MDL may be separated from the base BA of the first detection device AA1 (as shown in FIG. 5-2), and then the carrier platform CA carrying the display module MDL may be fixed to the base BA of the second detection device AA2 (as shown in FIG. 5-3). In this way, the display module MDL does not need to be separated from the carrier platform CA during the transfer, which avoids the repeated crimping between the display module MDL and the carrier platform CA, and further reduces a risk of quality damage to the display module during the detection.

In an embodiment of the present disclosure, referring to FIG. 3, the display module MDL includes a display panel and a flexible circuit board coupled to the display panel in a bounding manner. The flexible circuit board may be coupled with a control component (such as a circuit board, etc.) in a display device, so that a signal of the control component can be sent to the display panel. When the detection of the display module MDL is performed, the detection device may send a signal to the display panel through the flexible circuit board, and then detect a response of the display panel (including but not limited to an electrical response and an optical response). It can be understood that in some embodiments of the present disclosure, the display module may further include other components, such as a glass cover, a backplane, etc.

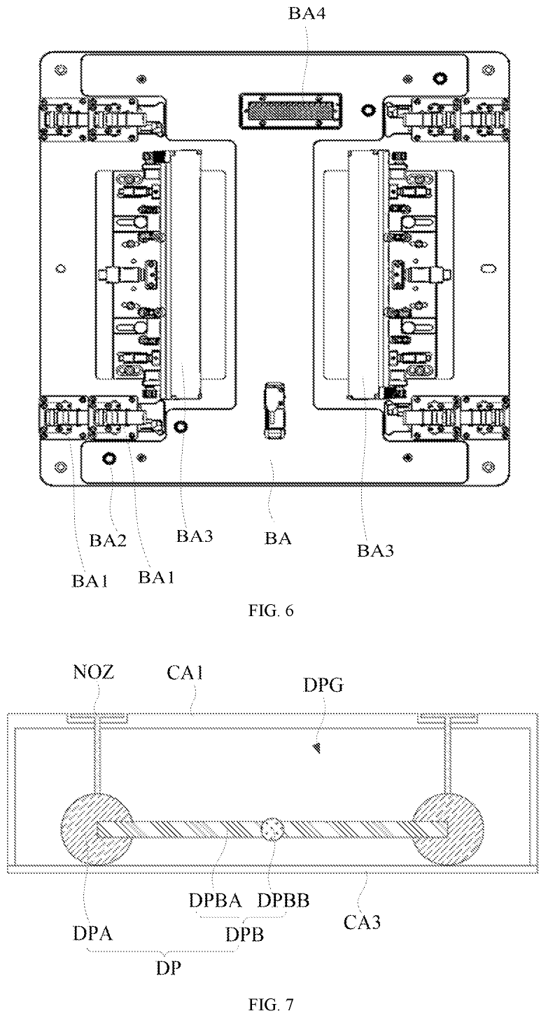

In an embodiment of the present disclosure, referring to FIG. 3, the carrier platform CA may further include a crimping table CA2 provided with a crimping joint JA. The display panel of the display module MDL may be carried on the carrier unit CA1 and adsorbed and fixed by the suction nozzle NOZ. The flexible circuit board of the display module MDL may be crimped with the crimping joint JA to achieve an electrical connection. In this way, the display module MDL to be detected and the carrier platform CA form a transferred workpiece. Referring to FIGS. 4 and 6, the base BA of the detection device has a fixing mechanism BA1 and a transfer circuit BA4, the base BA may fix the carrier platform CA through the fixing mechanism BA1, and the transfer circuit BA4 may be detachably electrically connected to the crimping joint JA. In this way, the detection device may load a signal to the display module MDL through the transfer circuit BA4 of the base BA and the crimping joint JA of the carrier platform CA, and perform the corresponding detection. After the detection is completed, the transferred workpiece may be separated from the base BA. Specifically, the fixing mechanism BA1 of the base BA is allowed to release the carrier platform CA and the transfer circuit BA4 is separated from the crimping joint JA. In this way, the transferred workpiece can be transferred to the next detection device for the next detection process. In an example, the transfer circuit BA4 may be a probe module (such as a POGO module).

In an embodiment of the present disclosure, the carrier unit CA1 is detachably connected to the crimping table CA2. In this way, when a new display module MDL needs to be detected, the crimping table CA2 may be determined according to the flexible circuit board of the new display module MDL. When the crimping joint JA of the original crimping table CA2 does not match the new flexible circuit board, an adapted crimping table CA2 may be replaced to be used for the carrier platform CA, so that the carrier platform CA is suitable for the new display Module MDL. In this way, parts of the carrier platform CA other than the crimping table CA2 may be shared in the detection of different display modules MDL, which can improve the versatility of the carrier platform CA, reduce the cost of the carrier platform CA, and reduce the switching time during the switching between n the detection of the different display modules MDL.

In an example, the crimping table CA2 is located on a side of the carrier unit CA1 in a first direction. When the display module MDL is carried on the carrier platform CA, the display panel is carried on the carrier unit CA1 and fixed by the suction nozzle NOZ. The flexible circuit board is located on the side of the display panel in the first direction to extend towards the crimping joint JA to be coupled to the crimping joint JA.

In embodiments of the present disclosure, two orthogonal directions in a plane where the carrier platform CA is located are called the first direction and a second direction, respectively. The crimping table CA2 is located on the side of the carrier unit CA1 in the first direction. A direction perpendicular to the plane where the carrier platform CA is located is called a third direction, and the first direction, the second direction, and the third direction are perpendicular to each other.

In an embodiment of the present disclosure, the carrier platform CA further includes a base plate CA3. Referring to FIG. 2, the carrier unit CA1 and the crimping table CA2 are fixed on the same side of the base plate CA3. For example, the carrier unit CA1 and the crimping table CA2 are both located on a side (an upper side) of the base plate CA3 in the third direction

In some embodiments of the present disclosure, the crimping table CA2 is detachably connected to the base plate CA3, so that the carrier unit CA1 and the crimping table CA2 are detachably connected. When the crimping table CA2 for the carrier platform CA needs to be replaced, the original crimping table CA2 may be separated from the base plate CA3, and a new crimping table CA2 may be connected to the base plate CA3.

In an embodiment of the present disclosure, referring to FIG. 7, there is an accommodation cavity DPG between the bottom plate CA3 and the carrier unit CA1, and a negative pressure assembly DP is at least partially accommodated in the accommodation cavity DPG. In this way, the negative pressure assembly DP is at least partially housed inside the carrier platform CA, which improves cleanliness of the carrier platform and prevents the negative pressure assembly DP from being externally placed to cause increased difficulty in operation and maintenance.

In some embodiments of the present disclosure, the accommodation cavity DPG is opened in the carrier unit CA1, and the bottom plate CA3 covers an opening of the accommodation cavity DPG. For example, the carrier unit CA1 includes a top plate and side walls connected to edges of the top plate. The top plate and the side walls surround the accommodation cavity DPG, and the bottom plate CA3 covers the opening of the accommodation cavity DPG. The top plate is provided with a suction nozzle cavity configured to accommodate the suction nozzle NOZ. In this example, the accommodation cavity DPG is opened in the carrier unit CA1 and opens downward, and the bottom plate CA3 is located below the accommodation cavity DPG and covers the opening of the accommodation cavity DPG to protect the negative pressure assembly DP located in the accommodation cavity DPG.

In an example, the side walls include two first side walls located on both sides of the top plate in the second direction. The top plate is sandwiched between the two first side walls in the second direction. The first side walls are sandwiched between the top plate and the bottom plate CA3 in the third direction. In this way, the accommodation cavity DPG is enclosed by the first side walls in the second direction to prevent foreign objects on both sides (the both sides in the second direction) of the accommodation cavity DPG from entering the accommodation cavity DPG.

It can be understood that the bottom plate CA3 may also have other side walls, or a support column configured to provide support between the top plate and the bottom plate CA3, etc., which is not particularly limited by the present disclosure.

It can be understood that in other embodiments of the present disclosure, the accommodation cavity DPG may also be opened in the bottom plate CA3, and the carrier unit CA1 as the top plate may cover the accommodation cavity DPG. In this case, the side wall located between the top plate and the bottom plate CA3 may be located on the bottom plate CA3. Alternatively, the accommodation cavity DPG may include a first accommodation cavity opened in the carrier unit CA1 and a second accommodation cavity opened in the bottom plate CA3. Openings of the first accommodation cavity and the second accommodation cavity are opposite and in communication with each other, together forming the accommodation cavity DPG configured to accommodate at least part of the structure of the negative pressure assembly DP.

In an embodiment of the present disclosure, referring to FIG. 7, the negative pressure assembly DP includes an air chamber structure DPA and a negative pressure control member DPB, the air chamber structure DPA has an air chamber with a variable capacity, and the negative pressure control member DPB is configured to control a capacity change of the air chamber to control whether to generate the negative pressure. The air chamber is connected with the suction nozzle NOZ. In an embodiment of the present disclosure, the negative pressure control member DPB may squeeze the air chamber structure DPA or stretch the air chamber structure DPA to control the capacity of the air chamber. For example, the negative pressure control member DPB may squeeze the air chamber structure DPA or stretch the air chamber structure DPA along the first direction. It can be understood that when the suction nozzle connected to the air chamber is blocked, if the capacity of the air chamber increases, an air pressure in the air chamber will decrease.

In some embodiments of the present disclosure, each air chamber structure DPA is disposed in the accommodation cavity DPG to ensure the stability of the air chamber structure DPA and the clean appearance of the carrier platform CA.

In some embodiments of the present disclosure, the negative pressure control member DPB may be partially located outside the accommodation cavity DPG and connected to the air chamber structure DPA. In this way, an operator can control the air chamber structure DPA outside the carrier platform CA.

In an embodiment of the present disclosure, the air chamber structure DPA is elastic, the negative pressure control member DPB is configured to compress the air chamber structure DPA to compress the air chamber, and the compressed air chamber structure DPA can cause the compressed air chamber to rebound during the rebound process, thereby generating the negative pressure in the air chamber. In this way, when it is necessary to provide the negative pressure to the suction nozzle NOZ, the negative pressure control member DPB may be made to compress the air chamber structure DPA, and then the negative pressure control member DPB is released. At this time, under the elasticity of the air chamber structure DPA, the air chamber structure DPA rebounds and in turn drives the compressed air chamber to rebound. The rebound of the air chamber causes the capacity of the air chamber to expand to cause the generation of the negative pressure inside it. If there is the display module MDL at the suction nozzle NOZ, the display module MDL will block the suction nozzle NOZ and be adsorbed by the suction nozzle NOZ, and in this case, the negative pressure in the air chamber connected to the suction nozzle will be maintained. When the negative pressure control member DPB compresses the air chamber structure DPA again, the air chamber may be compressed to cause the negative pressure at the suction nozzle NOZ to disappear, thereby causing the display module MDL to be released.

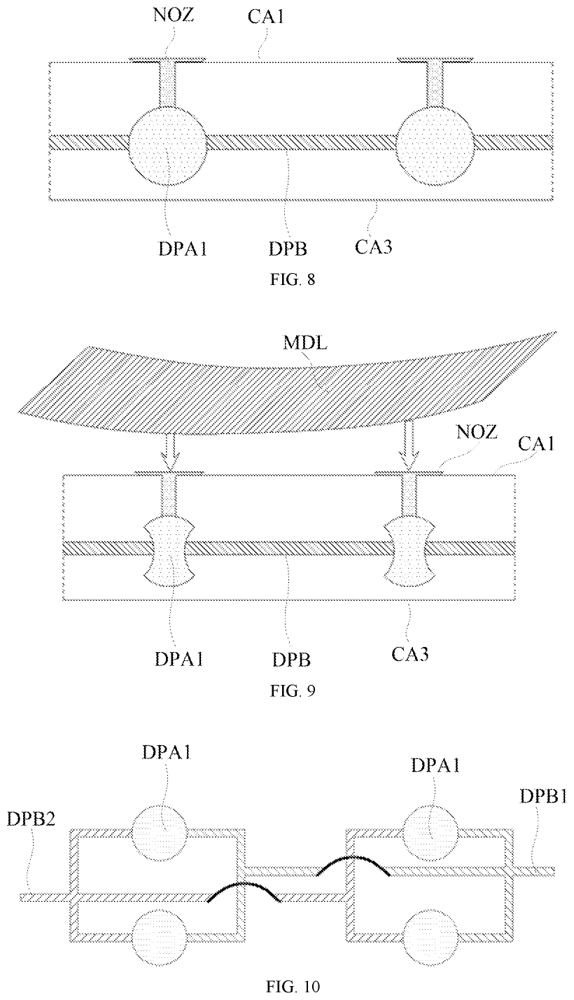

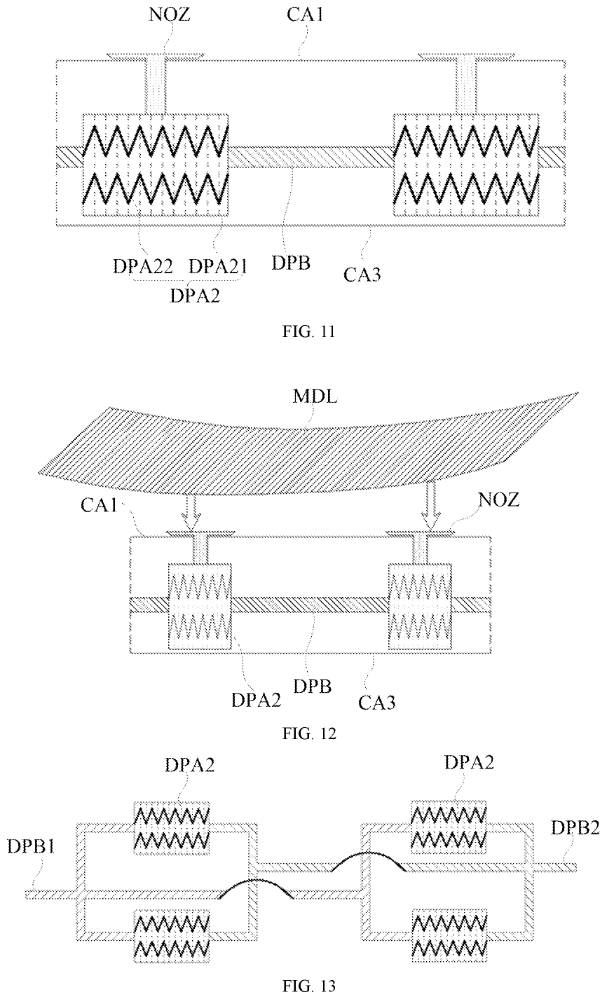

In an embodiment of the present disclosure, the air chamber structure DPA includes an elastic hollow ball DPA1 (as shown in FIG. 8), an elastic airbag, a resilient box DPA2 (as shown in FIG. 11) or a resilient cylinder, or it may be another elastic air chamber structure DPA. The elasticity of the air chamber structure DPA may come from the elasticity of a material of an air chamber wall. Alternatively, an additional elastic member DPA22 may be provided in the air chamber structure DPA to provide the elasticity required for the rebound of the air chamber.

For example, a material of the elastic hollow ball DPA1 and the elastic airbag (that is, the material of the air chamber wall) may be one or more of elastic silicone, elastic rubber or elastic plastic, or may be another elastic material.

In an example, referring to FIG. 8, the air chamber structure DPA is the elastic hollow ball DPA1. The material of the elastic hollow ball DPA1 is elastic silicone, and a cavity of the elastic hollow ball DPA1 serves as the air chamber to be connected to the suction nozzle NOZ. Referring to FIG. 9, when the elastic hollow ball DPA1 is squeezed by the negative pressure control member DPB, a volume of the elastic hollow ball DPA1 contracts, causing its air chamber to contract, and discharging part of the air therein. When the negative pressure control member DPB is released (the negative pressure control member DPB no longer squeezes the elastic hollow ball DPA1), the elastic hollow ball DPA1 has a tendency to rebound under the action of an elastic force, that is, the air chamber has a tendency to expand. During the rebound of the elastic hollow ball DPA1, if the suction nozzle NOZ is in contact with the display module MDL, the suction nozzle NOZ will be blocked by the display module MDL, generating and maintaining the negative pressure inside the hollow ball, thereby making the suction nozzle NOZ adsorb the display module MDL. It can be understood that when the suction nozzle NOZ adsorbs the display module MDL, the elastic hollow ball DPA1 may fully rebound or partially rebound, as long as the negative pressure is present and maintained in the air chamber. It can be understood that if the suction nozzle NOZ is not in contact with the display module MDL, the elastic hollow ball DPA1 will suck air from the suction nozzle NOZ under the action of the negative pressure during the rebound process, thereby causing the negative pressure in the air chamber to be quickly weakened and disappear, and accordingly, the suction nozzle NOZ will not adsorb the display module MDL.

For another example, referring to FIG. 11, the resilient box DPA2 includes a box DPA21 (such as a flexible box DPA21 or a foldable box DPA21) and an elastic member DPA22 located in the box DPA21. An internal space of the box DPA21 serves as the air chamber to be connected to the suction nozzle NOZ. Referring to FIG. 12, when the negative pressure control member DPB compresses the box DPA21, the elastic member DPA22 will deform to generate a rebound force. During the compression process, a volume of the box DPA21 contracts, causing its air chamber to contract and discharging part of the air therein. When the negative pressure control member DPB is released (the negative pressure control member DPB no longer squeezes the box DPA21), the elastic member DPA22 rebounds to expand the air chamber, that is, the box DPA21 rebounds under the rebound force of the elastic member DPA22. In this way, the negative pressure is generated in the air chamber and provided to the suction nozzle NOZ. During the rebound process of the box DPA21, if the suction nozzle NOZ is in contact with the display module MDL, the suction nozzle NOZ will be blocked by the display module MDL, generating and maintaining the negative pressure inside the box DPA21, thereby making the suction nozzle NOZ adsorb the display module MDL. It can be understood that when the suction nozzle NOZ adsorbs the display module MDL, the box DPA21 may fully rebound or partially rebound, as long as the negative pressure is present and maintained in the air chamber. It can be understood that if the suction nozzle NOZ is not in contact with the display module MDL, the box DPA21 will suck air from the suction nozzle NOZ under the action of the negative pressure during the rebound process, thereby causing the negative pressure in the air chamber to be quickly weakened and disappear, and accordingly, the suction nozzle NOZ will not adsorb the display module MDL. In embodiments of the present disclosure, the resilient box DPA2 achieves the rebound by virtue of the elasticity of the elastic member, which can ensure the rebound effect and improve the life of the resilient box DPA2.

In an example, the elastic member DPA22 located in the resilient box DPA2 may be a compression spring. When the compression spring is compressed, it provides the rebound force. Further, an extension direction of the compression spring is consistent with a deformation direction of the box DPA21. For example, the extension direction of the compression spring is the first direction.

In an example, the foldable cabinet DPA21 may be a bellows-type box DPA21.

For yet another example, the resilient cylinder includes a cylinder, a piston and an elastic member. There is an air chamber between the cylinder and the piston, and the elastic member is disposed in the air chamber. When the negative pressure control member compresses the cylinder, for example, when squeezing forces in opposite directions are applied to the cylinder and the piston, the piston and the cylinder slide relative to each other to compress the air chamber, and then discharge part of the air in the air chamber. During this process, the elastic member deforms to generate the rebound force. When the negative pressure control member is released, the elastic member rebounds to push the piston or the cylinder, thereby making the air chamber rebound and expand.

It can be understood that in each of the above examples, the negative pressure control member DPB compressing the air chamber structure DPA and then the air chamber being made to expand are taken as an example to illustrate the negative pressure assembly DP and the way to generate the negative pressure. In the above examples, the negative pressure control member DPB compresses the air chamber structure DPA to compress the air chamber to discharge part of the air in the air chamber. When no external force is applied to the negative pressure control member DPB, the air chamber structure DPA expands the air chamber under the action of the rebound force, and the negative pressure is generated during the expansion process of the air chamber. In these examples, when the negative pressure is required, the operator only needs to squeeze the air chamber structure DPA through the negative pressure control member DPB, and then no longer controls the negative pressure control member DPB, without the need to lock or fasten the negative pressure control member DPB, etc., achieving the advantage of simple operation.

In other embodiments of the present disclosure, the negative pressure may also be generated in a manner that the negative pressure control member DPB is used to expand the air chamber structure DPA. For example, the negative pressure control member DPB may stretch the air chamber structure DPA to expand the air chamber, thereby generating the negative pressure in the air chamber. In this case, if the suction nozzle NOZ is in contact with the display module MDL, the display module MDL will block the suction nozzle NOZ, making the display module MDL adsorbed under the negative pressure. The negative pressure control member DPB may be locked by a locking member to prevent the negative pressure control member DPB from rebounding to cause the air chamber to rebound, thereby maintaining the negative pressure in the air chamber. When the air chamber structure DPA contracts to cause the air chamber to contract, for example, the negative pressure control member DPB is released to cause the air chamber structure DPA to contract under its own rebound force, or the external force controls the negative pressure control member DPB to squeeze the air chamber structure DPA to cause the air chamber structure DPA to contract, the negative pressure in the air chamber may disappear, thereby making the adsorbed display module MDL released.

In an embodiment of the present disclosure, referring to FIG. 7, there are a plurality of air chamber structures DPA in a one-to-one correspondence with a plurality of suction nozzles NOZ. Any one of the air chamber structures DPA is configured to provide the corresponding suction nozzle NOZ with the negative pressure. In this way, the air chamber structure DPA that provides the negative pressure and the suction nozzle NOZ are provided in the one-to-one correspondence, which can ensure the stability of the adsorption and reduce the risk of adsorption failure. When any suction nozzle NOZ fails to adsorb, it will only cause the negative pressure in the air chamber structure DPA corresponding to the suction nozzle NOZ to dissipate, without affecting other air chamber structures DPA, thereby avoiding affecting the adsorption of other suction nozzles NOZ on the display module.

In an embodiment of the present disclosure, the negative pressure control member DPB includes a push rod, which is configured to compress or expand the air chamber of the air chamber structure DPA. By pulling or pushing the push rod, the compression or the expansion of the air chamber structure DPA may be achieved. It can be understood that the compression or the expansion of the air chamber structure DPA is not necessarily caused by the movement of the push rod. For example, when the compressed air chamber structure DPA rebounds and expands under the action of the rebound force, a power source of the expansion may be the rebound force of the air chamber structure DPA itself rather than a pulling force of the push rod. In some cases, the push rod may also serve as a follower and be pushed as the air chamber structure DPA expands. For another example, when the expanded air chamber structure DPA rebounds and contracts under the action of the rebound force, the power source of the contraction may be the rebound force of the air chamber structure DPA itself rather than a pushing force of the push rod. In some cases, the push rod may also serve as the follower and be pulled as the air chamber structure DPA contracts.

In an embodiment of the present disclosure, referring to FIGS. 10 and 13, the push rod includes a first push rod DPB1 and a second push rod DPB2 that cooperate with each other. The first push rod DPB1 is configured to apply a first squeezing force to the air chamber structure DPA, and the second push rod DPB2 is configured to apply a second squeezing force to the air chamber structure DPA. The first squeezing force and the second squeezing force have the same magnitude and opposite directions, for example, both are along the first direction. In this way, the air chamber structure DPA can be compressed under the squeezing of the first push rod DPB1 and the second push rod DPB2. In an example, since both sides of the air chamber structure DPA in the first direction are simultaneously squeezed, the air chamber structure DPA may exhibit a centripetal contraction characteristic. This is conducive to maintaining the stability of a center of the air chamber and in turn conducive to maintaining a relatively stable positional relationship between the air chamber structure DPA and the suction nozzle NOZ, and prevents the center of the air chamber structure DPA from shifting due to an uneven force to prevent this shifting from affecting the suction nozzle NOZ to cause damage to the adsorbed display module MDL.

In another embodiment of the present disclosure, it is not necessary to provide two push rods that cooperate with each other, but one push rod is used to compress the air chamber structure DPA. Specifically, a blocking member may be provided to block the air chamber structure DPA, so as to prevent the air chamber structure DPA from shifting under the pushing of the push rod. Alternatively, a fixing member may be provided to fix the air chamber structure DPA. In this way, when the push rod squeezes the air chamber structure DPA, the air chamber structure DPA is compressed without shifting. For example, a side of the air chamber structure DPA is provided with the blocking member (such as a baffle pre-fixed on the top plate or the bottom plate CA3), and the push rod is configured to apply the squeezing force to the other side of the air chamber structure DPA. In this way, under the joint squeezing of the blocking member and the push rod, the air chamber structure DPA may be squeezed to exhaust.

In an embodiment of the present disclosure, referring to FIGS. 10 and 13, there are a plurality of air chamber structures DPA. The negative pressure control member simultaneously controls respective air chamber structures DPA.

For example, the push rod includes a handle, a main rod body DPBB and a plurality of transmission mechanisms DPBA. The handle is disposed at an end of the main rod body and is located outside the carrier platform. The plurality of transmission mechanisms DPBA are connected to the main rod body DPBB, and connected to respective air chamber structures DPA in a one-to-one correspondence. In this way, the operator can push or pull the main rod body DPBB through the handle, and the main rod body DPBB drives the transmission mechanism DPBA, so that respective transmission mechanisms DPBA simultaneously apply forces (such as squeezing forces or expansion forces) to respective air chamber structures DPA. In embodiments of the present disclosure, the transmission mechanism DPBA and the air chamber structure DPA are connected, which may be connected through a hinge, a flexible joint or the like to make the transmission mechanism DPBA and the air chamber structure DPA become a whole, or may means that the air chamber structure DPA and the transmission mechanism DPBA are in contact with each other to be connected, for example, the air chamber structure DPA is abutted with the transmission mechanism DPBA. In an example, the transmission mechanism DPBA may be a side branch rod, a side plate, a lever mechanism, or another structure that can apply a force to the air chamber structure DPA according to the movement of the main rod body DPBB.

In examples of FIGS. 10 and 13, a thick black arc is used to indicate that a main rod body DPBB of a push rod and a transmission mechanism DPBA of another push rod do not interfere with each other. For example, the two push rods may be disposed at different heights to avoid each other. Alternatively, the main rod body DPBB of the push rod and the transmission mechanism DPBA of the other push rod may be disposed at different heights, or the main rod body DPBB of the push rod may be bent to avoid the transmission mechanism DPBA of the other push rod, or the transmission mechanism DPBA of the push rod is provided with a through hole that allows the main rod body DPBB of the other push rod to pass through, etc.

In some other embodiments of the present disclosure, the negative pressure assembly may include a negative pressure pump group and a control switch group. Under the control of the control switch group, the negative pressure pump group may provide the negative pressure for the suction nozzle. It can be understood that the negative pressure pump group may include one negative pressure pump or a plurality of negative pressure pumps, and the control switch group may include one control switch or a plurality of control switches. In an embodiment of the present disclosure, the negative pressure pump group includes a negative pressure module and negative pressure control valves in a one-to-one correspondence with respective suction nozzles. The negative pressure module includes one or more negative pressure pumps configured to generate the negative pressure. The suction nozzle is connected to the negative pressure module through the corresponding negative pressure control valve. The control switch group is configured to control the on or off of each negative pressure control valve, or control opening of each negative pressure control valve, so as to control whether the negative pressure pump group provides the negative pressure for the suction nozzle. In embodiments of the present disclosure, the negative pressure module may include one negative pressure pump, or a plurality of negative pressure pumps connected in parallel or in series, as long as these negative pressure pumps can provide the negative pressure for the negative pressure control valve. If necessary, the negative pressure module may further include other structures. For example, the negative pressure module may further include a buffer chamber. A suction port of each negative pressure pump is connected to the buffer chamber, and each negative pressure control valve is connected with the buffer chamber. In embodiments of the present disclosure, when a suction nozzle requires the negative pressure, a negative pressure control valve corresponding to the suction nozzle may be opened by means of the control switch group, or the opening of the negative pressure control valve may be controlled by means of the control switch group, so that the negative pressure module can provide the negative pressure to the suction nozzle.

In an example, when the suction nozzle needs the negative pressure, the control switch group may continuously turn on the negative pressure control valve corresponding to the suction nozzle, so that the negative pressure module continuously provides the negative pressure for the suction nozzle, reducing the failure risk of the suction nozzle.

In another example, when the suction nozzle requires the negative pressure, the control switch group may turn on the negative pressure control valve corresponding to the suction nozzle, and close the negative pressure control valve after the suction nozzle obtains the negative pressure. At this time, the display module blocks the suction nozzle, thereby maintaining the negative pressure in the suction nozzle. For example, the control switch group may make the negative pressure control valve opened for a preset time and then closed, for example, the negative pressure control valve may be opened for 1 to 3 seconds and then closed. For yet another example, the negative pressure assembly may also be provided with a pressure sensor configured to monitor the negative pressure in the suction nozzle. After the control switch group turns on the negative pressure control valve, the negative pressure in the corresponding suction nozzle may also be obtained according to the pressure sensor. After the negative pressure in the suction nozzle reaches an expected negative pressure, the control switch group may control the negative pressure control valve to close.

In an example, the control switch group may include control switches in a one-to-one correspondence with respective negative pressure control valves. These control switches may include one or more of mechanical switches such as push button switches and touch switches, or electronic switches.

In another example, the control switch group may include a remote control module. The remote control module may obtain and execute control instructions for respective negative pressure control valves through Bluetooth, WIFI, NFC or other wireless communication modes, thereby controlling the on or off of the respective negative pressure control valves, or controlling the opening of the negative pressure control valves.

In an example, the negative pressure module may further include a negative pressure release valve, and the control switch group is further configured to control the on or off of the negative pressure release valve. When the display module needs to be released, the negative pressure release valve may be opened and the negative pressure control valve corresponding to the suction nozzle with the negative pressure may be opened, thereby releasing the negative pressure in the suction nozzle and then releasing the display module. In other examples of the present disclosure, the negative pressure release valve may not be provided, but other methods may be used to controllably release the negative pressure in the suction nozzle.

It can be understood that the above introduction to the negative pressure module, the negative pressure control valve, and the control switch group is only an illustrative introduction, and the negative pressure module, the negative pressure control valve, and the control switch group in embodiments of the present disclosure are not limited to the above examples.

In another embodiment of the present disclosure, the negative pressure pump group may include a plurality of negative pressure pumps in a one-to-one correspondence with respective suction nozzles, and the negative pressure pump is connected to the corresponding suction nozzle. The control switch group controls whether each negative pressure pump is turned on or not, and then controls whether each suction nozzle can obtain the negative pressure provided by the negative pressure pump. When a suction nozzle requires the negative pressure, the control switch group may control a negative pressure pump corresponding to the suction nozzle to operate, thereby providing the required negative pressure to the suction nozzle.

In an example, the control switch group may include control switches in a one-to-one correspondence with respective negative pressure pumps. These control switches may include one or more of mechanical switches such as push button switches and touch switches, or electronic switches.

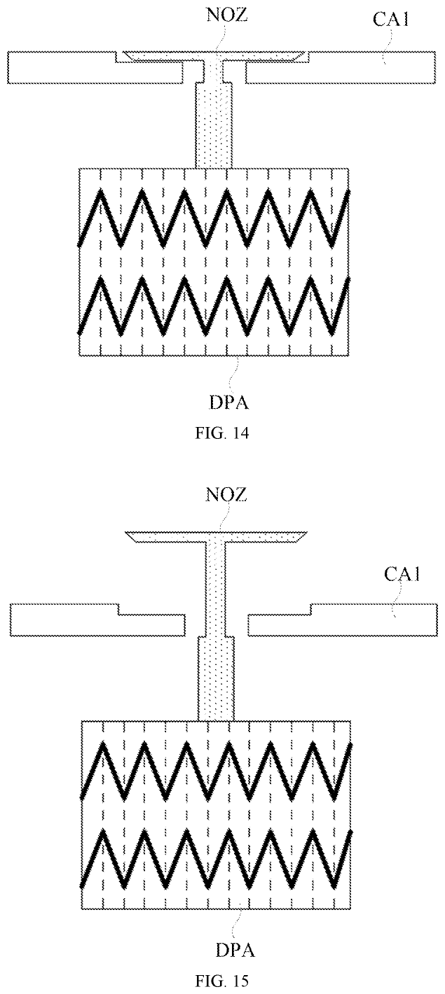

In another example, the control switch group may include a remote control module. The remote control module may obtain and execute control instructions for respective negative pressure pumps through Bluetooth, WIFI, NFC or other wireless communication modes, thereby controlling which negative pressure pumps work. In an embodiment of the present disclosure, referring to FIGS. 14 and 15, the suction nozzle NOZ is a retractable suction nozzle NOZ. Referring to FIG. 14, the suction nozzle NOZ is retracted in the suction nozzle cavity in the first state and cannot contact the display module MDL, and in this case, the suction nozzle NOZ cannot adsorb the display module MDL. Referring to FIG. 15, the suction nozzle NOZ extends out of the suction nozzle cavity in the second state, and in this case, the suction nozzle NOZ can contact the display module MDL, thereby adsorbing the display module MDL. In this way, by controlling which suction nozzles NOZ are in the first state and which suction nozzles NOZ are in the second state, the number and the distribution of suction nozzles NOZ configured to adsorb the display module MDL can be controlled to adapt to adsorption requirements required by different display modules MDL, which can greatly improve the versatility of the carrier platform CA for the display modules MDL of various shapes and sizes.

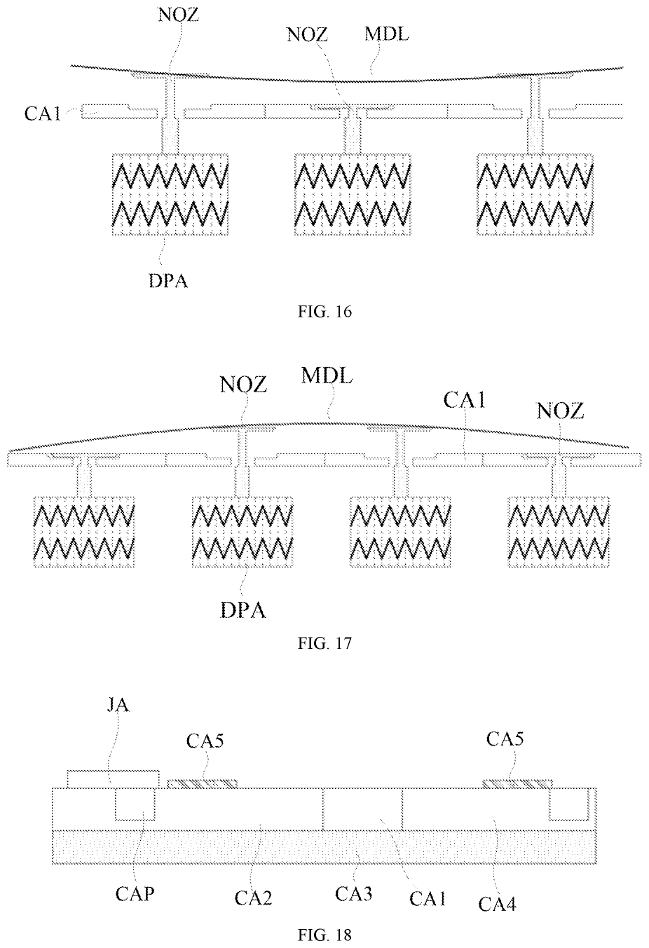

For example, in an example of FIG. 16, the display module MDL has a convex structure on both sides, and accordingly, the suction nozzles NOZ on both sides can be pulled out to be in the second state, and the nozzles NOZ in the middle can be retracted to be in the first state. In this way, the display module MDL can be adsorbed at the convex structure on both sides, which can ensure the stability of the display module MDL after being adsorbed. For another example, in an example of FIG. 17, the display module MDL has a convex structure in the middle, so that the suction nozzle NOZ in the middle can be pulled out to be in the second state, and the suction nozzles NOZ on both sides can be retracted to be in the first state. In this way, the display module MDL can be adsorbed at the convex structure in the middle, which can ensure the stability of the display module MDL after being adsorbed.

Therefore, in embodiments of the present disclosure, a plurality of retractable suction nozzles NOZ are disposed on the carrier unit CA1, so that the suction nozzles NOZ can adjust their states according to a structural characteristic of the display module MDL, thereby achieving an optimal adsorption effect and improving the stability of the module MDL after adsorption.

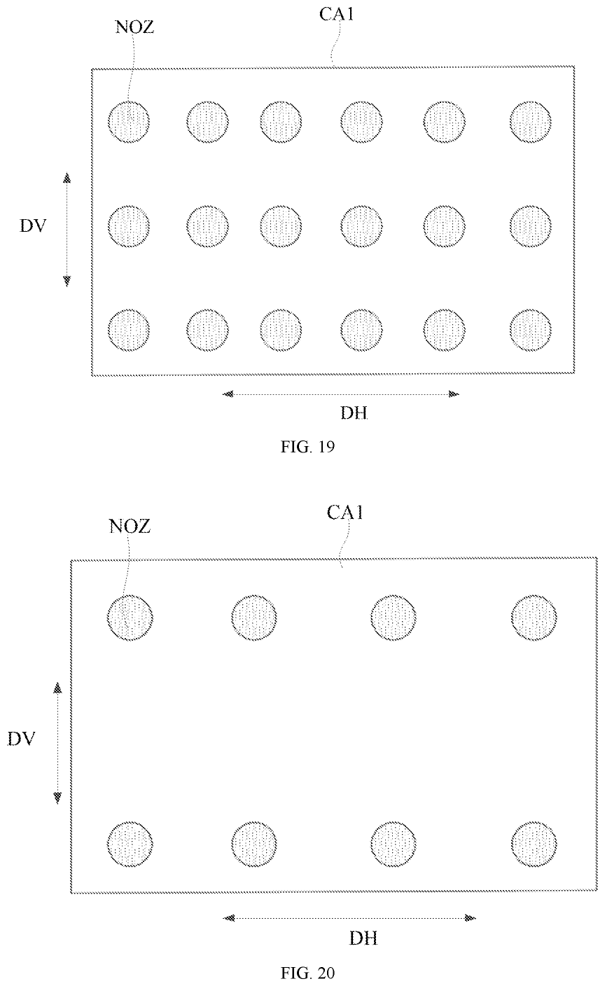

In an embodiment of the present disclosure, referring to FIG. 19, the carrier platform CA includes a plurality of suction nozzles NOZ distributed in an array, for example, the carrier platform CA may include M*N suction nozzles NOZ distributed in an array, and these suction nozzles NOZ are arranged in M rows and in N columns, where M and N are positive integers not less than 2. In embodiments of the present disclosure, the first direction DH is used as the row direction, and the second direction DV is used as the column direction. In other words, the suction nozzle rows include a plurality of suction nozzles NOZ arranged in sequence along the second direction, and the suction nozzle columns include a plurality of suction nozzles NOZ arranged in sequence along the first direction.

In some embodiments of the present disclosure, the plurality of suction nozzles NOZ are arranged densely, for example, a distance between two adjacent suction nozzles NOZ is not greater than 25 mm. In this way, the carrier platform CA is provided with the plurality of densely distributed suction nozzles NOZ, so that the carrier platform CA is suitable for various shapes of display modules MDL. According to the shape of the display module MDL, part of the suction nozzles NOZ can be extended out of the suction nozzle cavities and serve as active suction nozzles NOZ (in the second state), which can be adapted to the back of the display module MDL to adsorb the display module MDL, and the remaining suction nozzles NOZ (in the first state) are in the suction nozzle cavities and do not participate in the adsorption of the display module MDL.

For example, in an example of FIG. 19, the carrier platform CA is provided with three suction nozzle rows, each of which has six suction nozzles NOZ. It can be understood that the larger the size of the carrier unit CA1 of the carrier platform CA, the more the provided suction nozzle rows, and the greater the number of suction nozzles in each suction nozzle row.

In another embodiment of the present disclosure, the carrier platform CA may be provided with lower density and regularly arranged suction nozzles NOZ, for example, the distance between adjacent suction nozzles NOZ is not less than 35 mm. In this way, the carrier platform CA is suitable for adsorbing the flat display module MDL.

In an example, referring to FIG. 20, the carrier platform CA is provided with a plurality of suction nozzle rows (for example, two suction nozzle rows), each of which includes a plurality of suction nozzles NOZ, for example, 2 to 8 suction nozzles (e.g. four suction nozzles). It can be understood that the larger the size of the carrier unit CA1 of the carrier platform CA, the more the provided suction nozzle rows, and the greater the number of suction nozzles in each suction nozzle row.

In some other embodiments of the present disclosure, the suction nozzles NOZ on the carrier platform CA may also be arranged irregularly to adapt to a special-shaped display module MDL.

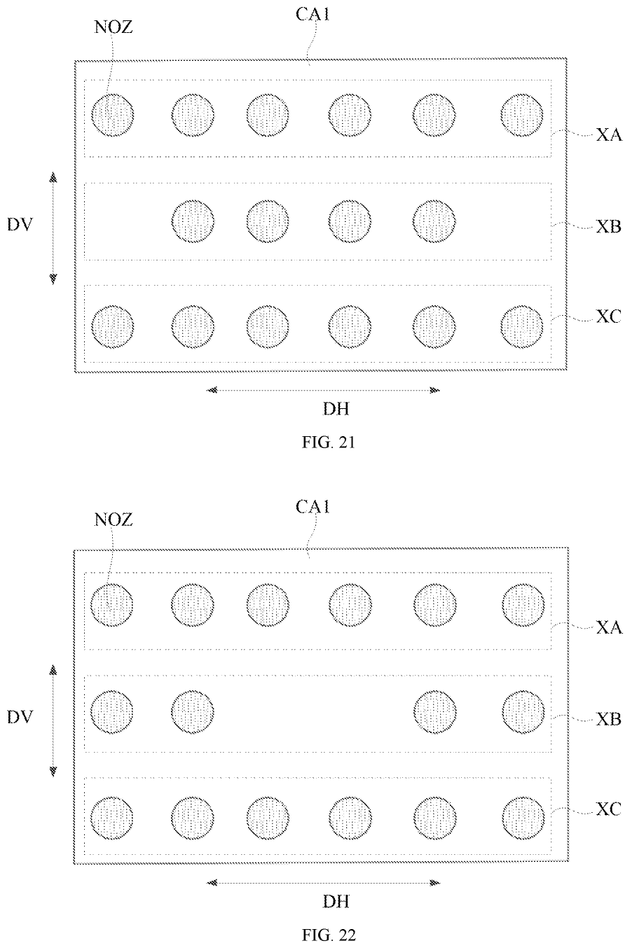

In an example, referring to FIG. 21, the carrier unit CA1 is divided into three areas of a first area XA, a second area XB, and a third area XC in sequence along the second direction DV, where a width of a suction nozzle row in the first area XA and a width of a suction nozzle row in the third area XC are greater than a width of a suction nozzle row in the second area XB. No suction nozzles NOZ are provided at both ends of the second area XB. In this way, the carrier platform CA is suitable for a C-type concave and convex display module MDL.

In an example, referring to FIG. 22, the carrier unit CA1 is divided into three areas of a first area XA, a second area XB, and a third area XC in sequence along the second direction DV. The suction nozzle rows include a plurality of suction nozzles NOZ arranged at equal intervals in sequence in the first area XA and the third area XC, and the suction nozzle row is further provided in the second area XB, but no suction nozzles are provided in the middle of the second area XB. In other words, no suction nozzle may be provided in the middle area of the carrier unit CA1. In this way, the carrier platform CA is suitable for adsorbing and fixing a bilaterally asymmetric display module MDL such as a S-shaped display module MDL.

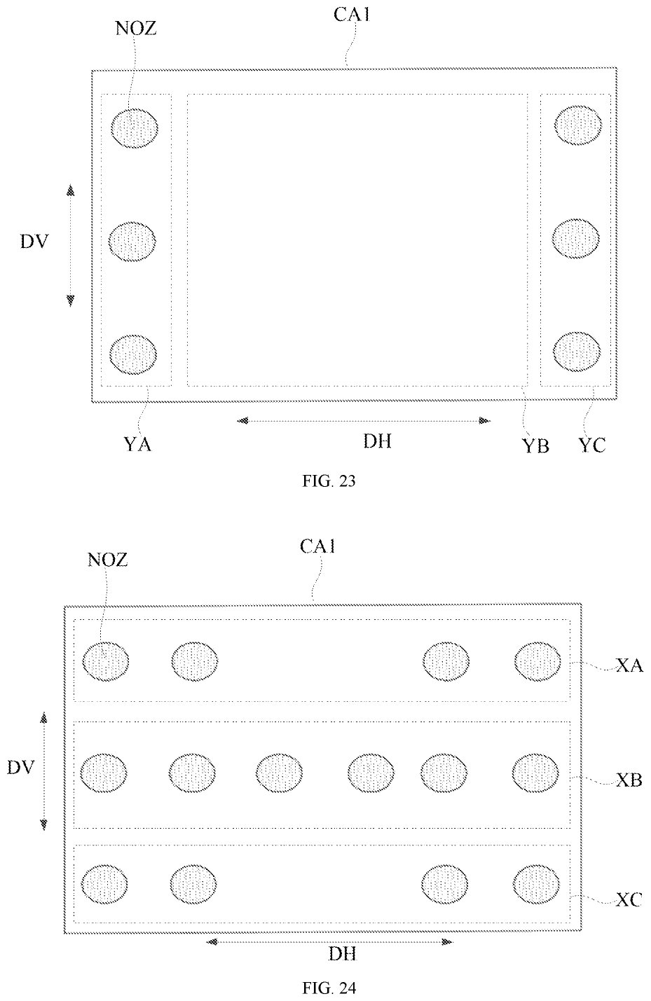

In an example, referring to FIG. 23, the carrier unit CA1 sequentially includes a fourth area YA, a fifth area YB, and a sixth area YC along the first direction DH. The fourth area YA and the sixth area YC are provided with a suction nozzle column, and each suction nozzle column includes a plurality of suction nozzles arranged at equal intervals in sequence along the second direction DV. No suction nozzles NOZ are provided in the fifth area YB. In this way, the carrier platform CA is suitable for a display module MDL with a special shape in the middle of the display module MDL.

In an example, referring to FIG. 24, the carrier unit CA1 is divided into three areas of a first area XA, a second area XB, and a third area XC in sequence along the second direction DV Suction nozzle rows are provided in these three areas of the first area XA, the second area XB, and the third area XC. The suction nozzle row located in the second area XB includes a plurality of suction nozzles arranged at equal intervals in sequence, and the suction nozzle row located in the first area XA and the suction nozzle row located in the third area XC have the same width as the suction nozzle row located in the second area XB. However, the suction nozzle row located in the first area XA and the suction nozzle row located in the third area XC are not provided with the suction nozzles in the middle of the first area XA and in the middle of the third area XC. In this way, the carrier platform CA is suitable for a display module MDL in which three sections (for example, three sections of far, medium and near) of the display module MDL are asymmetrical.

In some embodiments of the present disclosure, referring to FIGS. 19 to 22, the suction nozzle NOZ may be a circular suction nozzle. Alternatively, referring to FIGS. 23 and 24, a suction nozzle with another shape may also be provided as needed. For example, an elliptical nozzle or a regular polygonal nozzle (such as a square nozzle, a regular hexagonal nozzles, etc.) is provided.

In an embodiment of the present disclosure, referring to FIG. 18, a flexible positioning piece CA5 may also be attached to a carrying face of the carrier unit CA1, and the flexible positioning piece is tearably adhered to a surface of the carrier unit CA1. The flexible positioning piece is configured to cooperate with an edge of the display module to position the display module. For example, flexible positioning pieces CA5 are provided on both sides of the display module in the first direction to position the display module, which not only improves the stability of the fixation of the display module on the carrier unit, but also improves the accuracy of the positioning of the display module on the carrier unit.

In an embodiment of the present disclosure, when the carrier platform CA needs to carry a new display module, the position of the flexible positioning piece CA5 may be adjusted according to the new display module, so that the carrier platform CA can adapt to different display modules.

In embodiments of the present disclosure, the flexible positioning piece CA5 is flexible, which can avoid the quality damage to the edge of the display module, have a certain buffering effect and help to maintain the quality of the display module.

In an example, a material of the flexible positioning piece may be foam, such as a foam block or a foam strip. The foam has a good compression ability, which can position the edge of the display module more firmly and provide the better buffering effect.

In an embodiment of the present disclosure, referring to FIGS. 1 to 3, the carrier platform CA may further include a connection part CA4 located at an end of the carrier unit CA1 away from the crimping table CA2. When the carrier platform CA is connected to the base BA, the fixing mechanism BA1 on the base BA may be connected to the connection part CA4 to achieve the fixation of the connection part CA4.

It can be understood that the fixing mechanism BA1 on the base BA may also be fixed with another part of the carrier platform CA. For example, referring to FIG. 4, when the carrier platform CA is connected to the base BA, the fixing mechanism BA1 on the base BA is fixed to the crimping table CA2 and the connection part CA4 to further improve the fixation stability.

In an example, both the crimping table CA2 and the connection part CA4 are provided with crimping grooves CAP at their edges. The fixing mechanism BA1 has a gripper that can extend into the crimping groove CAP to grasp (for example, crimp or clamp) the carrier platform CA, thereby achieving the fixation of the carrier platform CA.

In an example, the fixing mechanism BA1 further includes a cylinder mechanism configured to control the gripper.

In an example, the crimping table CA2 is provided with two crimping grooves CAP, which are respectively located at two opposite edges of the crimping table CA2. Specifically, the two crimping grooves CAP are respectively located at both sides of the crimping table CA2 in the second direction.

In an example, the connection part CA4 is provided with two crimping grooves CAP, which are respectively located at two opposite edges of the connection part CA4. Specifically, the two crimping grooves CAP are respectively located at both sides of the connection part CA4 in the second direction.

In an embodiment of the present disclosure, the carrier platform CA is further provided with a positioning hole CAH, which penetrates the carrier platform CA along the third direction. The base BA is provided with a positioning column BA2 configured to cooperate with the positioning hole CAH. When the carrier platform CA is fixed to the base BA, the positioning column BA2 is inserted into the positioning hole CAH to position the carrier platform CA.

In an embodiment of the present disclosure, the fixing mechanism BA1 and the positioning column BA2 that cooperate with the same carrier platform CA are used as a set of positioning connection components as a whole. The base BA is provided with a plurality of sets of positioning connection components, each set of positioning connection components can cooperate with the carrier platform CA of the same size, and different sets of positioning connection components can cooperate with carrier platforms CA of different sizes. In this way, the base BA can be adapted to a variety of different carrier platforms CA, which can improve the versatility of the detection device.

For example, in the base BA shown in FIG. 6, the base BA is provided with two sets of positioning connection components, and each set of positioning connection components includes a plurality of positioning columns BA2 and four fixing mechanisms BA1. A size of a carrier platform CA to which a first set of positioning connection components is adapted is smaller than a size of a carrier platform CA to which a second set of positioning connection components is adapted. In the example of FIG. 4, the carrier platform CA cooperates with the second set of positioning connection components to achieve the fixation of the carrier platform CA and the base BA.

In an embodiment of the present disclosure, a side face (the side face of a side in the first direction) of the connection part CA4 may be provided with a push rod hole HA for the push rod to pass through, and the main rod body DPBB of the push rod passes through the push rod hole HA, and the handle is disposed outside the connection part CA4.

When the negative pressure control member DPB includes two push rods that cooperate with each other, a side face (the side face of a side in the first direction) of the crimping table CA2 may also be provided with a push rod hole HA for the push rod to pass through. The main rod body DPBB of the push rod passes through the push rod hole HA, and the handle is disposed outside the crimping table CA2. In this way, the carrier platform includes two handles arranged oppositely along the first direction, and the adsorption and the release of the display module can be realized by controlling the two handles.

In an embodiment of the present disclosure, the connection part CA4 and the carrier unit CA1 are located on the same side of the bottom plate CA3, for example, both are located on an upper side of the bottom plate. Furthermore, the connection part CA4 and the carrier unit CA1 may be an integrally formed structure.

In an embodiment of the present disclosure, referring to FIG. 2, the carrier platform CA is provided with prism avoidance cavities CAG on both sides of the carrier unit CA1 in the second direction. At least part of the base BA that cooperates with the carrier platform CA is provided with a prism component BA3, which can be accommodated in the prism avoidance cavity CAG to detect the side of the display module MDL. With the help of the refraction and/or the reflection of light by the prism component BA3, the detection device may detect an edge position of the display module MDL, especially side edges of large-angle screens or special-shaped screens. Further, the prism component BA3 has an angle adjustment mechanism and a prism, and the angle adjustment mechanism may adjust an angle of the prism.

In an embodiment of the present disclosure, the base plate CA3 of the carrier platform CA has an integrated structure. A gap may be provided between the crimping table CA2 and the connecting part CA4 to reduce the consumables and weight of the crimping table CA2 and the connecting part CA4 while ensuring a structural strength of the carrier platform CA, and reduce the cost of the carrier platform CA.

Other embodiments of the present disclosure will be apparent to those skilled in the art from consideration of the specification and practice of the present disclosure disclosed herein. The present application is intended to cover any variations, uses, or adaptations of the present disclosure, which are in accordance with the general principles of the present disclosure and include common general knowledge or conventional technical means in the art that are not disclosed in the present disclosure. The specification and embodiments are illustrative, and the real scope and spirit of the present disclosure is defined by the appended claims.

1. A carrier platform, comprising:
a carrier unit, configured to carry a display module;
a suction nozzle, disposed on the carrier unit; and
a negative pressure assembly, configured to provide a negative pressure to the suction nozzle to enable the suction nozzle to adsorb the display module located on the carrier unit.

2. The carrier platform according to claim 1, wherein the negative pressure assembly comprises an air chamber structure and a negative pressure control member, the air chamber structure is equipped with an air chamber with a variable capacity, and the negative pressure control member is configured to control a capacity change of the air chamber to control whether to generate the negative pressure.

3. The carrier platform according to claim 2, wherein the air chamber structure is elastic, and the negative pressure control member is configured to compress the air chamber structure to compress the air chamber; and
the compressed air chamber structure is capable of rebounding under action of elasticity to cause the air chamber to rebound and generate the negative pressure.

4. The carrier platform according to claim 2, wherein the air chamber structure comprises an elastic hollow ball, an elastic air bag, a resilient box or a resilient cylinder.

5. The carrier platform according to claim 4, wherein a material of the elastic hollow ball is elastic silicone or elastic rubber.

6. The carrier platform according to claim 4, wherein the resilient box comprises a flexible box or a foldable box and an elastic member located in the box.

7. The carrier platform according to claim 2, wherein a plurality of suction nozzles are provided, a plurality of air chamber structures are provided and have a one-to-one correspondence with the plurality of suction nozzles, and any air chamber structure is configured to provide the negative pressure to a corresponding suction nozzle.

8. The carrier platform according to claim 2, wherein the carrier platform further comprises a bottom plate, an accommodation cavity is disposed between the bottom plate and the carrier unit, and the air chamber structure is accommodated in the accommodation cavity.

9. The carrier platform according to claim 2, wherein the negative pressure control member comprises a push rod, configured to compress or expand the air chamber of the air chamber structure.

10. The carrier platform according to claim 9, wherein the push rod comprises a first push rod and a second push rod cooperated with each other, the first push rod is configured to apply a first squeezing force to the air chamber structure, the second push rod is configured to apply a second squeezing force to the air chamber structure, and the first squeezing force and the second squeezing force are the same in magnitude and opposite in direction.

11. The carrier platform according to claim 2, wherein a plurality of air chamber structures are provided, and respective air chamber structures are simultaneously controlled by the negative pressure control member.

12. The carrier platform according to claim 1, wherein the negative pressure assembly comprises a negative pressure pump group and a control switch group, and the negative pressure pump group is capable of providing the negative pressure for the suction nozzle under control of the control switch group.

13. The carrier platform according to claim 1, wherein the carrier unit is provided with a suction nozzle cavity, and the suction nozzle is accommodated in the suction nozzle cavity;
any suction nozzles is a retractable suction nozzle;
the suction nozzle is contractible into the suction nozzle cavity in a first state; and
the suction nozzle is extendable out of the suction nozzle cavity in a second state.

14. (canceled)

15. The carrier platform according to claim 1, wherein the carrier platform further comprises a flexible positioning piece located on a surface of the carrier unit, and the flexible positioning piece is tearably adhered to the surface of the carrier unit; and the flexible positioning piece is configured to cooperate with an edge of the display module to position the display module.

16. The carrier platform according to claim 1, wherein the carrier platform further comprises a crimping table provided with a crimping joint;
a flexible circuit board of the display module is capable of being crimped with the crimping joint; and
wherein the crimping table is detachably connected to the carrier unit.

17. The carrier platform according to claim 1, wherein the carrier platform is provided with prism avoidance cavities on both sides of the carrier unit; and
at least part of a base that is cooperated with the carrier platform is provided with a prism component, and the prism component is capable of being accommodated in a prism avoidance cavity to detect a side of the display module.

18. A base for a detection device, configured to be in a detachable connection with a carrier platform, wherein the carrier platform comprises:
a carrier unit, configured to carry a display module;
a suction nozzle, disposed on the carrier unit; and
a negative pressure assembly, configured to provide a negative pressure to the suction nozzle to enable the suction nozzle to adsorb the display module located on the carrier unit,
wherein the carrier platform is provided with prism avoidance cavities on both sides of the carrier unit; and
at least part of a base that is cooperated with the carrier platform is provided with a prism component, and the prism component is capable of being accommodated in a prism avoidance cavity to detect a side of the display module;
wherein the base is provided with two sets of prism components; and
in a case that the base is connected with the carrier platform, the two sets of prism components are capable of being accommodated in two prism avoidance cavities in a one-to-one correspondence.

19. A base for a detection device, configured to be in a detachable connection with a carrier platform, wherein the carrier platform comprises:
a carrier unit, configured to carry a display module;
a suction nozzle, disposed on the carrier unit; and
a negative pressure assembly, configured to provide a negative pressure to the suction nozzle to enable the suction nozzle to adsorb the display module located on the carrier unit,
wherein the carrier platform further comprises a crimping table provided with a crimping joint;
a flexible circuit board of the display module is capable of being crimped with the crimping joint;
the crimping table is detachably connected to the carrier unit;
the base is equipped with a replaceable transfer circuit; and
in a case that the carrier platform is connected with the base, the transfer circuit is capable of being electrically connected to the crimping joint.

20. A base for a detection device, configured to be in a detachable connection with the carrier platform according to claim 1;
the base is provided with a plurality of sets of positioning connection components, and the carrier platform is detachably connected to the base through the positioning connection components; and
different positioning connection components are capable of being detachably connected to different carrier platforms.

21. A detection device, comprising the base according to claim 18.
